(19) United States
(12) Patent Application Publication
(10) Pub. No.: US 2012/0019995 A1
(43) Pub. Date: Jan. 26, 2012

(54) EMBEDDED SYSTEM AND METHOD FOR ADJUSTING CONTENT

(75) Inventor: TENG-YU TSAI, Tu-Cheng (TW)

(73) Assignee: HON HAI PRECISION INDUSTRY CO., LTD., Tu-Cheng (TW)

(21) Appl. No.: 13/096,571

(22) Filed: Apr. 28, 2011

(30) Foreign Application Priority Data
Jul. 26, 2010 (CN) 201010236823.6

(51) Int. Cl. H05K 7/00

(52) U.S. Cl. 361/679.01

(57) ABSTRACT

An embedded system includes a display, an area positioning module, a background module, a content adapter, and a data sliding module. The area positioning module is configured to define a position and a size of a display area. The background module is configured to create a background layer corresponding to the display area. Color of the background layer gradually varies from a first end of the background layer to a middle of the background layer along a first direction. The content adapter is configured to provide the initialized date or time. The data sliding module is configured to create a sliding layer for displaying content. The sliding layer is substantially transparent; the data sliding module is further configured to control the sliding layer to slide along the first direction.

### BACKGROUND

1. Technical Field

The present disclosure relates to embedded systems, and particularly to, an embedded system and method for adjusting content.

2. Description of Related Art

Typically, there is a date or time adjustment function in an embedded system. Usually, users can adjust the date or time on a touch panel of a device, and there is a three dimensional effect in the user interface. However, the effect is provided by the processor and may take up many resources of the processor, which may cause the speed of the device to slow.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of an embedded system in accordance with an embodiment.

FIG. 2 is a schematic view of a background layer and a sliding layer.

FIG. 3 is a schematic view of a background layer.

FIG. 4 is a schematic view of a sliding layer.

FIG. 5 is a schematic view of a background layer and a sliding layer.

FIG. 6 is a schematic view of a background layer and a sliding layer when the sliding layer is slid.

FIG. 7 is a flow chart of a method for adjusting date or time in accordance with an embodiment.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

In general, the word “module,” as used herein, refers to logic embodied in hardware or firmware, or to a collection of software instructions, written in a programming language, such as, for example, Java, C, or Assembly. One or more software instructions in the modules may be embedded in firmware, such as an EPROM. It will be appreciated that modules may comprise connected logic units, such as gates and flip-flops, and may comprise programmable units, such as programmable gate arrays or processors. The modules described herein may be implemented as either software and/or hardware modules and may be stored in any type of computer-readable medium or other computer storage device.

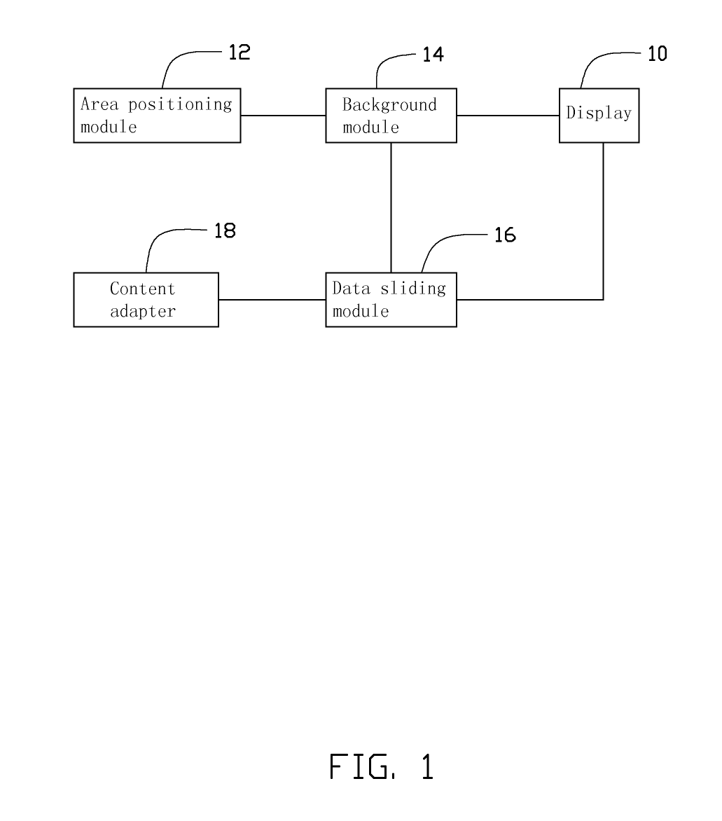

Referring to FIG. 1, an embedded system is installed in an electronic device, such as a smart phone, or a digital photo display. The embedded system includes a display 10, an area positioning module 12, a background module 14, a data sliding module 16, and a content adapter 18. The area positioning module 12 is connected to the background module 14. The background module 14 is connected to the display 10 and the data sliding module 16. The data sliding module 16 is connected to the content adapter 18 and the display 10.

The display 10 is configured to display user interfaces. In one embodiment, the display 10 is a touch panel. The area positioning module 12 is configured to define a position and a size of a display area for displaying predetermined content on the display 10. In one embodiment, the content may include date or time numbers, such as year, month, week, hour, minute, and second. In one embodiment, the display area defined by the area positioning module 12 is rectangular.

The background module 14 is configured to create a background layer in the area, for example, a gradually changing colored background image may be drawn in the area. In one embodiment, the color of the background layer may vary from light to dark from the middle to opposite ends of the background image.

The data sliding module 16 is configured to create a plurality of transparent or translucent data sliding layers. The data sliding module 16 is configured to control a corresponding data sliding layer to slide along a first direction. The data sliding module 16 is further configured to adjust the data of the corresponding data sliding layer when users touch the corresponding data sliding layer and slide a finger in the first direction.

The content adapter 18 is configured to provide the current date and time to the data sliding module 16. The data sliding module 16 is configured to initialize the date or time of the data sliding layers.

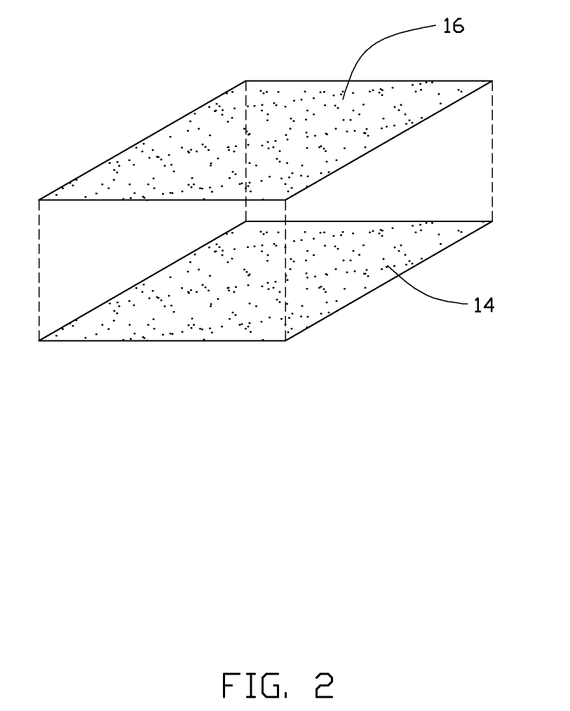

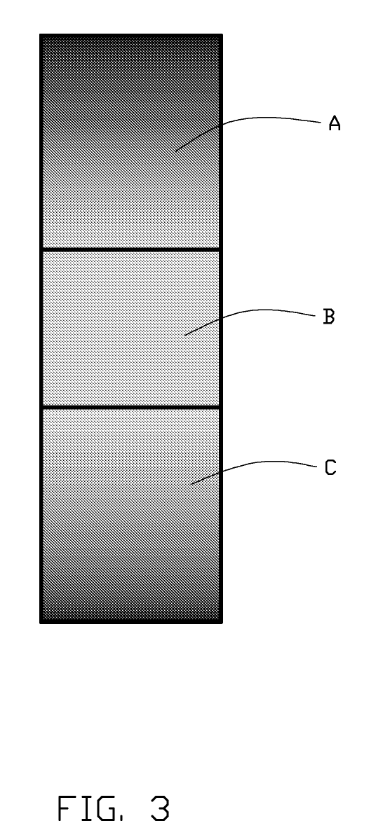

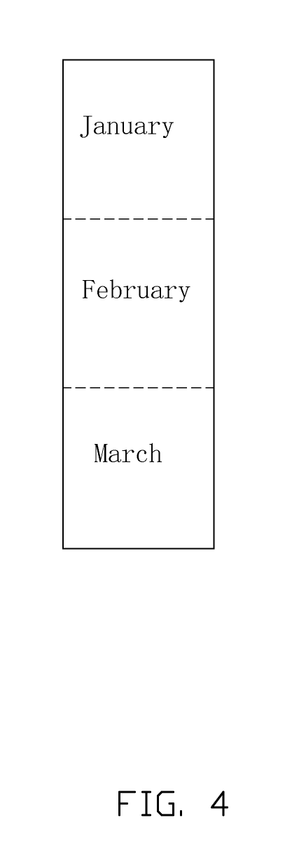

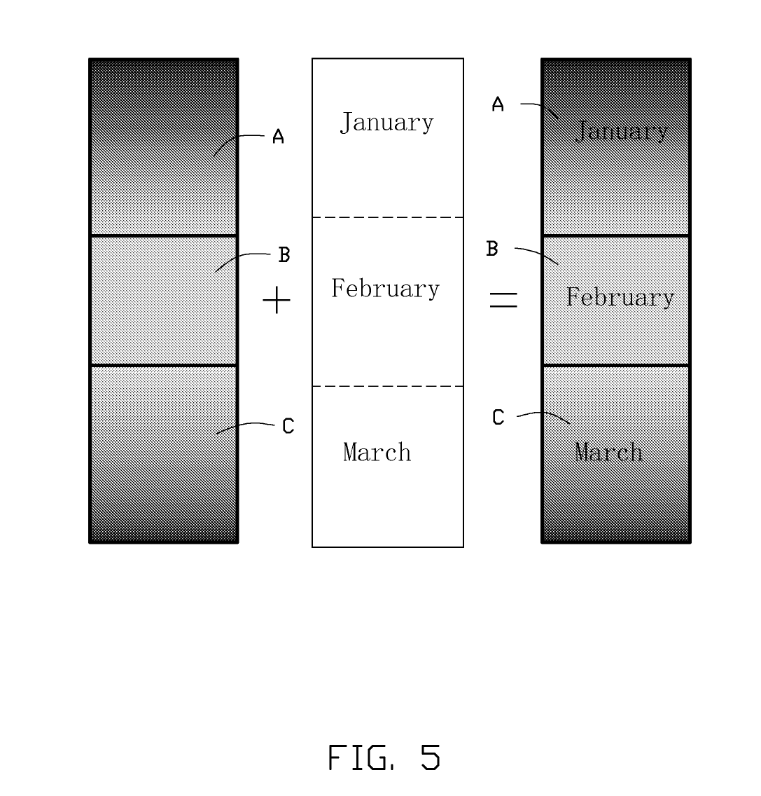

Referring to FIGS. 2, 3, 4, and 5, the background module 14 creates a background layer L1 in an area confirmed by the area positioning module 12. The length and the width of the background layer L1 are substantially and respectively equal to the length and the width of the sub area corresponding to the sub category. The background layer L1 includes three parts: part A, part B, and part C. The color in the part A linearly varies from dark to light as the position of the part A varies from up to down. The color in the part C linearly varies from dark to light as the position of the part C varies from down to up. The color in the part B is substantially the same as the color in part C adjacent to the part B and the color in part A, adjacent to the part B. The data sliding module 16 creates a data sliding layer L2. The background of the data sliding layer L2 is transparent. The size of the data sliding layer L2 corresponds to the size of the background layer L1. The data sliding layer L2 displays three values corresponding to the three parts of the background layer L1 respectively. The three values are a part of the date or time. For example, the three values are “January”, “February”, and “March”. “January” is displayed in the part A, “February” is displayed in the part B, and “March” is displayed in the part C.

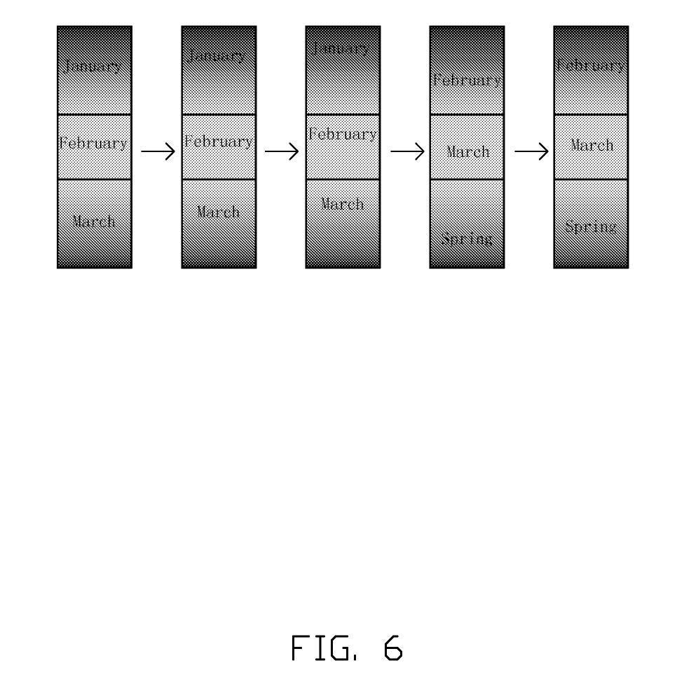

Referring to FIG. 6, the data sliding layer L2 slides from down to up when the data sliding module 16 receives a sliding command from down to up. Image “February” is displayed on the middle portion of the display area. The data sliding layer L2 moves a distance and then stops. At this time, image “March” is displayed on the middle portion of the display area.

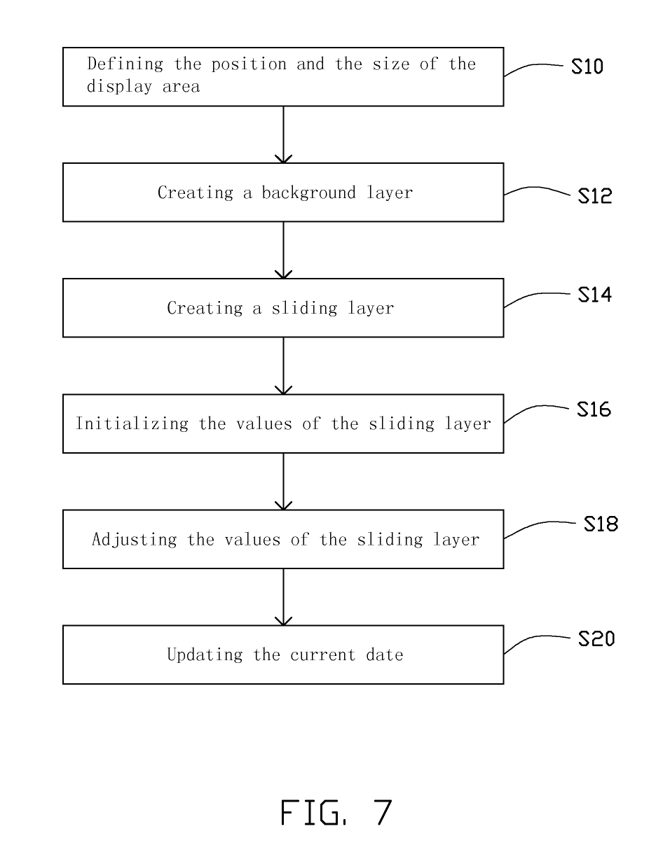

Referring to FIG. 7, a method for adjusting the date or time is shown below.

In step S10, the area positioning module 12 determines the position and the size of the display area of the display 10.

In step S12, the background module 14 creates a background layer corresponding to the display area.

In step S14, the data sliding module 16 creates a sliding layer corresponding to the display module.

In step S16, the data sliding module 16 initializes the value of the sliding layer according to the current date or time.

In step S18, the data sliding module 16 adjusts the current value according to the sliding command.

In step S20, the content adapter 18 update the date or time of the system according to the current value of the sliding layer.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

Depending on the embodiment, certain of the steps of methods described may be removed, others may be added, and the sequence of steps may be altered. It is also to be understood that the description and the claims drawn to a method may include some indication in reference to certain steps. However, the indication used is only to be viewed for identification purposes and not as a suggestion as to an order for the steps.

What is claimed is:

1. An embedded system comprising:
a display;
an area positioning module, the area positioning module configured to define a position and a size of a display area;
a background module, the background module configured to create a background layer corresponding to the display area, color of the background layer being gradually varied from a first end of the background layer to a middle of the background layer along a first direction;
a content adapter, the content adapter configured to provide an initialized date or time; and
a data sliding module, the data sliding module configured to create a sliding layer for displaying content, and the sliding layer is substantially transparent; the data sliding module further configured to control the sliding layer to slide along the first direction.

2. The embedded system of claim 1, wherein color of the background layer varies from dark to light as the first end of the background layer extends to the middle of the background layer.

3. The embedded system of claim 2, wherein the background layer comprises a first part, a second part connected to the first part, and a third part connected to the second part, and color of the first part gradually varies from dark to light along the first direction and color of the third part gradually varies from dark to light a second direction, that is opposite to the first direction.

4. The embedded system of claim 1, wherein the background layer comprises a second end, and color of the background layer varies from dark to light as the second end of the background layer moves to the middle of the background layer.

5. The embedded system of claim 1, wherein the area positioning module is further configured to store the position and the size to an extensible markup language file.

6. A content adjusting method comprising:
defining a position and a size of a display area of a display;
creating a background layer in the display area, color of the background layer being gradually varied from a first end of the background layer to a middle of the background layer along a first direction;
creating a sliding layer for displaying content corresponding to the display area, wherein the sliding layer is substantially transparent;
initializing content on the sliding layer;
moving the sliding layer along the first direction; and
updating content of the embedded system.

7. The content adjusting method of claim 6, wherein color of the background layer varies from dark to light as the first end of the background layer moves to a middle of the background layer.

8. The content adjusting method of claim 7, wherein the background layer comprises a first part, a second part connected to the first part, and a third part connected to the second part; and a color of the first part varies linearly from dark to light in a second direction and a color of the third part varies linearly from dark to light in a third direction, that is opposite to the second direction.

9. The content adjusting method of claim 6, wherein the background layer comprises a second end, and color of the background layer varies from dark to light as the second end of the background layer moves to the middle of the background layer.

10. The content adjusting method of claim 6, further comprising storing the position and the size to an extensible markup language file after defining the position and the size.

11. A content adjusting method comprising:
providing an embedded system, the embedded system comprising: a display; an area positioning module, the area positioning module configured to define a position and a size of a display area; a background module, the background module configured to create a background layer corresponding to the display area, color of the background layer being gradually varied from a first end of the background layer to a middle of the background layer along a first direction; a content adapter, the content adapter configured to provide an initialized date or time; and a data sliding module, the data sliding module configured to create a sliding layer for displaying content, and the sliding layer is substantially transparent; the data sliding module further configured to control the sliding layer to slide along the first direction;
defining the position and a size of the display area of the display;
creating the background layer in the display area, color of the background layer being gradually varied from the first end of the background layer to a middle of the background layer along the first direction;
creating the sliding layer for displaying content corresponding to the display area, wherein the sliding layer is substantially transparent;
initializing content on the sliding layer;
moving the sliding layer along the first direction; and
updating content of the embedded system.
